(19) United States
(12) Patent Application Publication
(10) Pub. No.: US 2012/0118356 A1
(43) Pub. Date: May 17, 2012

(54) MULTI-LAYER SOLAR MODULE BACKSHEET

(75) Inventors: Scot Albright, Tucson, AZ (US); Jeffrey S. Britt, Tucson, AZ (US)

(73) Assignee: Global Solar Energy, Inc., Tucson, AZ (US)

(21) Appl. No.: 13/104,568

(22) Filed: May 10, 2011

Related U.S. Application Data
(60) Provisional application No. 61/333,179, filed on May 10, 2010.

(51) Int. Cl. H01L 31/048

(52) U.S. Cl. 136/251

(57) ABSTRACT

Thin film photovoltaic modules that include strings of thin film cells laminated between a transparent flexible barrier layer and a multi-layer backsheet configured to stabilize the module and to reduce or control thermo-mechanical stresses leading to undesirable effects such as warping and ribbon buckling, among others. In some cases, the backsheet has an effective TEC that relatively closely matches the TEC of the cells, resulting in improved module stability. Alternatively or in addition, the backsheet may include one or more relatively thick flexible layers, again resulting in improved stability. Various materials may be used with TECs that are chosen to minimize a particular thermo-mechanical stress, and/or to provide a module with a predetermined amount of curvature.

### CROSS-REFERENCE TO RELATED APPLICATION

This application claims priority from U.S. Provisional Patent Application Ser. No. 61/333,179 filed May 10, 2010 which is incorporated herein by reference.

### BACKGROUND

The field of photovoltaics generally relates to multi-layer materials that convert sunlight directly into DC electrical power. The basic mechanism for this conversion is the photovoltaic effect, first observed by Antoine-César Becquerel in 1839, and first correctly described by Einstein in a seminal 1905 scientific paper for which he was awarded a Nobel Prize for physics. In the United States, photovoltaic (PV) devices are popularly known as solar cells or PV cells. Solar cells are typically configured as a cooperating sandwich of p-type and n-type semiconductors, in which the n-type semiconductor material (on one “side” of the sandwich) exhibits an excess of electrons, and the p-type semiconductor material (on the other “side” of the sandwich) exhibits an excess of holes, each of which signifies the absence of an electron. Near the p-n junction between the two materials, valence electrons from the n-type layer move into neighboring holes in the p-type layer, creating a small electrical imbalance inside the solar cell. This results in an electric field in the vicinity of the metallurgical junction that forms the electronic p-n junction.

When an incident photon excites an electron in the cell into the conduction band, the excited electron becomes unbound from the atoms of the semiconductor, creating a free electron/hole pair. Because, as described above, the p-n junction creates an electric field in the vicinity of the junction, electron/hole pairs created in this manner near the junction tend to separate and move away from junction, with the electron moving toward the electrode on the n-type side, and the hole moving toward the electrode on the p-type side of the junction. This creates an overall charge imbalance in the cell, so that if an external conductive path is provided between the two sides of the cell, electrons will move from the n-type side back to the p-type side along the external path, creating an electric current. In practice, electrons may be collected from at or near the surface of the n-type side by a conducting grid that covers a portion of the surface, while still allowing sufficient access into the cell by incident photons.

Such a photovoltaic structure, when appropriately located electrical contacts are included and the cell (or a series of cells) is incorporated into a closed electrical circuit, forms a working PV device. As a standalone device, a single conventional solar cell is not sufficient to power most applications. As a result, solar cells are commonly arranged into PV modules, or “strings,” by connecting the front of one cell to the back of another, thereby adding the voltages of the individual cells together in electrical series. Typically, a significant number of cells are connected in series to achieve a usable voltage. The resulting DC current then may be fed through an inverter, where it is transformed into AC current at an appropriate frequency, which is chosen to match the frequency of AC current supplied by a conventional power grid. In the United States, this frequency is 60 Hertz (Hz), and most other countries provide AC power at either 50 Hz or 60 Hz.

One particular type of solar cell that has been developed for commercial use is a “thin-film” PV cell. In comparison to other types of PV cells, such as crystalline silicon PV cells, thin-film PV cells require less light-absorbing semiconductor material to create a working cell, and thus can reduce processing costs. Thin-film based PV cells also offer reduced cost by employing previously developed deposition techniques for the electrode layers, where similar materials are widely used in the thin-film industries for protective, decorative, and functional coatings. Common examples of low cost commercial thin-film products include water impermeable coatings on polymer-based food packaging, decorative coatings on architectural glass, low emissivity thermal control coatings on residential and commercial glass, and scratch and anti-reflective coatings on eyewear. Adopting or modifying techniques that have been developed in these other fields has allowed a reduction in development costs for PV cell thin-film deposition techniques.

Furthermore, thin-film cells have exhibited efficiencies approaching 20%, which rivals or exceeds the efficiencies of the most efficient crystalline cells. In particular, the semiconductor material copper indium gallium diselenide (CIGS) is stable, has low toxicity, and is truly a thin film, requiring a thickness of less than two microns in a working PV cell. As a result, to date CIGS appears to have demonstrated the greatest potential for high performance, low cost thin-film PV products, and thus for penetrating bulk power generation markets. Other semiconductor variants for thin-film PV technology include copper indium diselenide, copper indium disulfide, copper indium aluminum diselenide, and cadmium telluride.

Some thin-film PV materials may be deposited either on rigid glass substrates, or on flexible substrates. Glass substrates are relatively inexpensive, generally have a coefficient of thermal expansion that is a relatively close match with the CIGS or other absorber layers, and allow for the use of vacuum deposition systems. However, when comparing technology options applicable during the deposition process, rigid substrates suffer from various shortcomings during processing, such as a need for substantial floor space for processing equipment and material storage, expensive and specialized equipment for heating glass uniformly to elevated temperatures at or near the glass annealing temperature, a high potential for substrate fracture with resultant yield loss, and higher heat capacity with resultant higher electricity cost for heating the glass. Furthermore, rigid substrates require increased shipping costs due to the weight and fragile nature of the glass. As a result, the use of glass substrates for the deposition of thin films may not be the best choice for low-cost, large-volume, high-yield, commercial manufacturing of multi-layer functional thin-film materials such as photovoltaics.

In contrast, roll-to-roll processing of thin flexible substrates allows for the use of compact, less expensive vacuum systems, and of non-specialized equipment that already has been developed for other thin film industries. PV cells based on thin flexible substrate materials such as thin sheets of stainless steel also exhibit a relatively high tolerance to rapid heating and cooling and to large thermal gradients (resulting in a low likelihood of fracture or failure during processing), require comparatively low shipping costs, and exhibit a greater ease of installation than cells based on rigid substrates. Additional details relating to the composition and manufacture of thin film PV cells of a type suitable for use with the presently disclosed teachings may be found, for example, in U.S. Pat. Nos. 6,310,281, 6,372,538, and 7,194,197, all to Wendt et al. These patents are hereby incorporated into the present disclosure by reference for all purposes.

As noted previously, a significant number of PV cells often are connected in series to achieve a usable voltage, and thus a desired power output. Such a configuration is often called a “string” of PV cells, and can be formed, for example, using conductive tabs or ribbons, where a given tab electrically connects one polarity of a first cell to the opposite polarity of an adjacent cell. The ribbons used to connect the cells can be formed from materials selected to provide good matching of thermal expansion coefficients (TEC) between the ribbons and the cells. For example, when the cells are formed on a stainless steel substrate, the ribbons can be formed from copper, stainless steel or some other material with a TEC similar to that of stainless steel. TEC matching between cells and ribbons limits mechanical stress upon the electrical connections between them when the string is thermally cycled. Further details about forming strings of photovoltaic cells can be found in U.S. Patent Application Publication No. 2009-0255565-A1 (corresponding to application Ser. No. 12/364,440 filed Feb. 2, 2009), which is hereby incorporated by reference into the present disclosure.

Usable solar modules can be constructed from strings by, for example, laminating the strings between glass and a multi-layer backsheet containing aluminum foil. A backsheet commonly used in the solar industry in this manner is constructed from successive layers of the polyvinyl fluoride material Tedlar®, aluminum foil, polyethylene terephthalate (PET) and ethylene vinyl acetate (EVA). One function of the aluminum foil layer in the backsheet is to act as a vapor barrier to limit water ingress into the strings, because thin film strings such as those incorporating CIGS are sensitive to water and may suffer performance degradation in its presence.

When laminated into the glass/backsheet package described above, mechanical stress upon a string of PV cells is minimized by the glass sheet on one side of the string, which serves as the “backbone” of the module. The stabilizing role of the glass sheet can be understood in terms of the TECs of the various materials. In the example described above, the overall TEC of the backsheet is largely determined by the TEC of the aluminum foil, which is approximately 22.2 parts per million per degree Kelvin (ppm/K). Stainless steel suitable for use as the substrate for the PV cells has a TEC of approximately 10.4 ppm/K, and suitable glass has a TEC of approximately 8.5 ppm/K. Even though the aluminum foil has a TEC substantially larger than stainless steel, the thick glass sheet on the front side of the PV is thought to limit mechanical stress on the PV from expansion and contraction of the aluminum foil (with greater TEC). However, the resulting module is rigid due to the glass sheet.

A flexible thin film module can be fabricated by replacing the glass sheet described above with a transparent polymer. However, transparent polymers typically have substantially larger TECs than glass, and also may undergo irreversible shrinkage upon first exposure to elevated temperatures. As a result, a transparent polymer does not serve the same “backbone” role in a module as a glass sheet. On the contrary, in a structure comprising a transparent polymer on the front and a backsheet including a layer of aluminum foil, the string may be exposed to relatively large thermo-mechanical stresses. This is due to thermal expansion and contraction of both the transparent polymer and the aluminum foil, with no layer serving as a “backbone” to provide sufficient countervailing stability.

In practice, it has been determined that when exposed to elevated temperatures (>85 C), flexible modules fabricated from thin film strings often experience undesirable thermo-mechanical stresses, leading, for example, to buckling of the conductive ribbons connecting the cells due to relative contraction of the laminate over the strings. The ribbon buckling is aesthetically unpleasing and presents a potential source for product failure, which can occur from electrical contact failure or from damage to the transparent barrier layer and subsequent ingress of water vapor. Accordingly, it would be desirable to construct flexible modules of thin film strings that avoid ribbon buckling of this type, and more generally to control the internal thermo-mechanical stresses of modules.

### SUMMARY

The present teachings disclose thin film photovoltaic modules that include strings of thin film cells laminated between a transparent flexible barrier layer and a multi-layer backsheet configured to stabilize the module and to reduce or control thermo-mechanical stresses leading to undesirable effects such as warping and ribbon buckling, among others. In some cases, the backsheet has an effective TEC that relatively closely matches the TEC of the cells, resulting in improved module stability. Alternatively or in addition, the backsheet may include one or more relatively thick flexible layers, again resulting in improved stability. Various materials may be used with TECs that chosen to minimize a particular thermo-mechanical stress, and/or to provide a module with a predetermined amount of curvature.

### BRIEF DESCRIPTION OF THE DRAWINGS

FIG. 1 is a perspective view showing two thin film photovoltaic cells coupled together by conductive ribbons, according to aspects of the present teachings.

FIG. 2 is a partially exploded schematic sectional view of a portion of a flexible thin film photovoltaic module, according to aspects of the present teachings.

### DETAILED DESCRIPTION

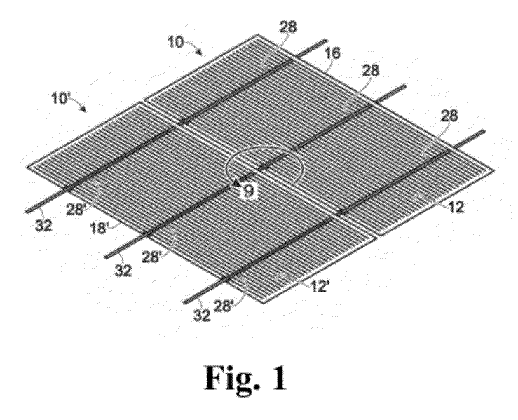

FIG. 1 shows two PV cells 10, 10′, connected in an electrical series (or string) by three electrically conductive ribbons 28, according to aspects of the present teachings. Cell 10′ is constructed in similar fashion to cell 10, and the cells typically will have a common width, length, and thickness. Primed reference numbers (e.g., 12′, 14′, etc.) designate portions of cell 10′ corresponding to similar portions of cell 10 designated by the same, unprimed reference numbers. Although exactly two cells are depicted in FIG. 1, the methods and apparatus disclosed herein are more generally applicable to any number of PV cells, and may be applied to a string or 2-dimensional array of any number of cells, depending on the desired voltage or power output for a particular PV cell application. For instance, a plurality of cells can be interconnected to form modules capable of producing 6, 12, 30, 60, or 120 Watts of power.

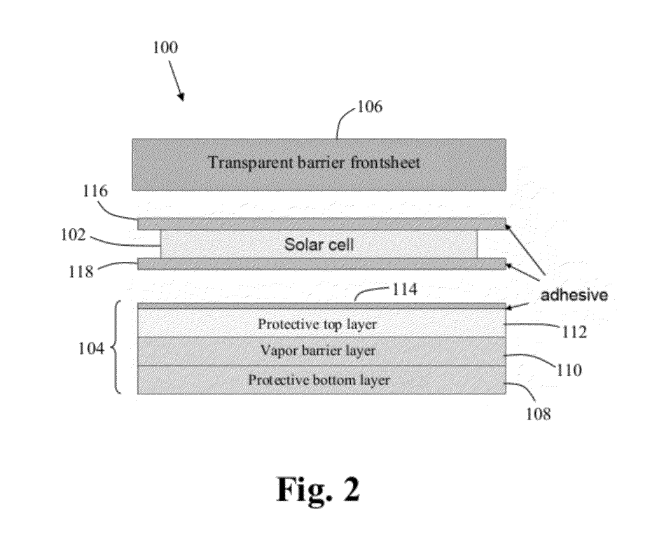

A portion of an exemplary flexible thin film photovoltaic module illustrating aspects of the present teachings is generally indicated at 100 in FIG. 2. Module 100 includes a thin film photovoltaic cell 102, a multi-layer backsheet generally indicated at 104, and a transparent barrier frontsheet 106. Cell 102 may be similar in its general characteristics to cells 10 and 10′ of FIG. 1, and typically will incorporate various thin film layers (not shown) including at least a substrate layer, one or more semiconductor absorber layers, and a transparent conductive layer. For example, the substrate layer may be constructed from a stainless steel foil, and the semiconductor absorber layer may be at least partially constructed from vacuum deposited CIGS. However, other materials for the substrate and the absorber layers are within the scope of the present teachings. Although only a single cell 102 is depicted in FIG. 2, module 100 will typically include a plurality of photovoltaic cells electrically interconnected by conductive ribbons, as depicted in FIG. 1.

Multi-layer backsheet 104 includes a protective bottom layer 108 formed of a material such as the polyvinyl fluoride material Tedlar® manufactured by the DuPont Corporation, a vapor barrier layer 110, a protective top layer 112 formed of a material such as polyethylene terephthalate (PET), and an adhesive encapsulating layer 114 formed of a material such as ethylene vinyl acetate (EVA). Protective bottom layer 108 sheds dirt and moisture, and provides electrical insulation between vapor barrier layer 110 and any support structure. Protective top layer 112 provides electrical insulation between vapor barrier layer 110 and cell 102.

Aside from Tedlar® and PET, other materials may be used in the protective top and bottom layers to accomplish similar purposes. Because protective bottom layer 108 is exposed to humidity and temperature, it may be constructed from a material having good hydrolytic stability, to reduce degradation of the polymer due to exposure to humidity at high temperature. This can improve adhesion and/or plasticity of the bottom layer, and may allow the layer to maintain its size after exposure to the elements. The same considerations apply to protective top layer 112, but to a lesser extent because that layer is generally not exposed to humidity and temperature to the same extent as the protective bottom layer. In some cases, the protective bottom and top layers may be formed of the same material. Although not shown in the illustration, adhesives are typically used to join vapor barrier layer 110 to protective bottom layer 108 and protective top layer 112.

Adhesive encapsulating layer 114 is configured to bond backsheet 104 to an encapsulant layer 118 beneath the photovoltaic material of the cell. A variety of materials other than ethylene vinyl acetate also may be suitable for this purpose, including without limitation polyvinyl butyral (PVB), ethylene copolymers, various ionomers, thermoplastic urethanes, silicones, polychlortrifluorethylene, fluorothermoplastics, and polyolefin copolymers. Because of its location below the photovoltaic cells in module 100, adhesive encapsulating layer 114 does not require transparency, but rather is chosen more for its adhesive properties.

Vapor barrier layer 110 acts to limit moisture ingress into cell 102 (and thus into the photovoltaic portion of module 100) from below. According to the present teachings, the vapor barrier layer may be constructed from a material having a thermal expansion coefficient chosen to minimize thermo-mechanical stress on at least a portion of the module. For example, stainless steel may be chosen as the material used in layer 110. Stainless steel may be particularly suitable for use in the backsheet due to its moisture impermeability, its flexibility, and because it has a TEC that matches the TEC of cell 102, which in this example is based on a stainless steel substrate.

Specifically, if the cell substrate and the vapor barrier layer are both constructed from stainless steel, this can minimize thermo-mechanical stress on the cells of the module during temperature variations of the module, resulting in potentially greater durability of the module. Similarly, if the conductive ribbons interconnecting the cells are also constructed from stainless steel, this can minimize thermo-mechanical stress on the ribbons, and possible undesirable ribbon buckling, during temperature variations of the module. In some cases, the stainless steel of the vapor barrier layer and/or the conductive interconnecting ribbons may be heat treated, for example by tempering or annealing, to attain desired ductility and to further minimize stresses between the various components of the module.

More generally, if the substrate, the vapor barrier layer and/or the conductive ribbons interconnecting the cells are constructed from materials having substantially similar coefficients of thermal expansion and appropriate ductility, this can result in decreased thermo-mechanical stress on one or more portions of the module. For example, the vapor barrier layer and/or the conductive interconnecting ribbons each may be constructed from copper, resulting in relatively greater compatibility in the thermal expansion characteristics of the module, even if the cell substrate is constructed from stainless steel. The present teachings contemplate any choice of material in the vapor barrier layer of the backsheet that provides improved thermal expansion matching between the backsheet, the photovoltaic cells, and the connecting ribbons between cells.

The thickness of vapor barrier layer 110 may be selected to provide sufficient thermo-mechanical stability to the module, while still allowing the module to retain a desired degree of flexibility. For example, a stainless steel or copper vapor barrier layer may have a thickness between 0.5 millimeters and 6 millimeters. At thicknesses greater than approximately 6 millimeters, most metallic materials are better characterized as a rigid sheet than as a flexible foil, and at thicknesses less than approximately 0.5 millimeters, metal foils are difficult to manufacture, expensive, and provide little influence as a stabilizing “backbone” within a solar module.

Transparent barrier frontsheet 106 will typically be formed from a transparent flexible polymer that acts to protect the underlying photovoltaic cells from environmental elements while still allowing substantial transmission of solar radiation. For example, various fluoropolymers applied either as flexible films or as liquids may be well suited as materials for the protective transparent frontsheet. However, the present teachings are not limited to any particular choice of frontsheet material, and may even be implemented with frontsheets that include glass or other rigid transparent materials.

When frontsheet 106 is constructed from a material that shrinks upon first exposure to elevated temperatures, according to the present teachings the frontsheet may be pre-shrunk prior to its disposition in module 100. Pre-shrinking the frontsheet in this manner may serve to further reduce potential thermo-mechanical stress on the underlying portions of the module. Furthermore, the present teachings contemplate the use of frontsheet materials having relatively low TECs, to better match the thermal expansion characteristics of the underlying portions of the module and further reduce the potential TEC mismatch between various portions of the module.

In addition pre-shrinking the frontsheet, the present teachings also contemplate pre-shrinking protective bottom layer 108 and/or protective top layer 112. Depending on the materials used in these layers, using pre-shrunk materials in the layers may help to avoid undesirable shrinking of the layers during lamination and/or during exposure to operating conditions, which in some cases can result in undesirable stresses on the resulting module.

As depicted in FIG. 1, layers of encapsulating adhesive material 116, 118 are typically applied to each side of cell 102 in module 100. Top encapsulating layer 116 will generally be substantially transparent to allow solar radiation to reach cell 102, whereas bottom encapsulating layer 118 need not be transparent due to its disposition below the cell. Encapsulating layers 116 and 118 suitable for use with the present teachings may be formed from any suitable materials, including without limitation any of the materials listed above with respect to encapsulating adhesive layer 114.

The description above generally relates to minimizing thermo-mechanical stresses in a photovoltaic module, i.e. bringing those stresses as close to zero as possible. In another approach contemplated by the present teachings, materials may be chosen to provide a photovoltaic module with a controlled amount of thermo-mechanical stress having a particular orientation. More specifically, the substrate, the vapor barrier layer, and the interconnecting ribbons may be constructed from one or more materials having coefficients of thermal expansion configured to provide the photovoltaic module with a predetermined amount of curvature.

For example, module materials may be provided having coefficients of thermal expansion configured to result in a predetermined amount of curvature that will match the curvature of a structure to which the module is configured to be attached, such as a curved roof, or to counteract adhesive creep of an adhesive used to hold the module to a mounting structure. Similarly, the predetermined amount of curvature may counteract adhesive creep of an adhesive used to hold the module to a mounting structure, and still retain curvature to match curvature of a structure to which the module will be attached.

In general, according to the present teachings a module may be constructed with any desired curvature characteristics. This may be accomplished through the choice of materials for the cell substrate, the vapor barrier layer, and/or the interconnecting conductive ribbons having coefficients of thermal expansion that differ by predetermined amounts. Desired curvature then may be attained, for example, during a subsequent heat treatment of the module (or portions thereof), such as during lamination of the frontsheet to the cells. Alternatively, the frontsheet may be pre-shrunk by exposure to an elevated temperature, and desired curvature of the module may be attained during manufacture by a dedicated heat treatment, or simply due to natural temperature fluctuations that will occur during and after the manufacturing process.

The disclosure set forth above may encompass multiple distinct inventions with independent utility. Although each of these inventions has been disclosed in its preferred form(s), the specific embodiments thereof as disclosed and illustrated herein are not to be considered in a limiting sense, because numerous variations are possible. The subject matter of the present teachings includes all novel and nonobvious combinations and subcombinations of the various elements, features, functions, and/or properties disclosed herein.

We claim:

1. A photovoltaic module, comprising:
a plurality of photovoltaic cells electrically interconnected by conductive ribbons, each cell including a semiconductor absorber layer and a substrate upon which the absorber layer is supported;
a transparent barrier frontsheet overlying the cells and configured to protect the cells from environmental elements while allowing substantial passage of solar radiation to the cells; and
a multi-layer backsheet underlying the cells and including a vapor barrier layer constructed from a material having a thermal expansion coefficient chosen to minimize thermo-mechanical stress on at least one of the cells or the conductive ribbons.

2. The module of claim 1, wherein the substrate and the vapor barrier layer are each constructed from stainless steel.

3. The module of claim 2, wherein the stainless steel of the vapor barrier layer is heat treated by a method selected from the set consisting of tempering and annealing.

4. The module of claim 1, wherein the vapor barrier layer and the conductive ribbons are each constructed from copper.

5. The module of claim 1, wherein the frontsheet is pre-shrunk by exposure to an elevated temperature.

6. The module of claim 1, wherein the frontsheet is constructed from a material having a thermal expansion coefficient chosen to minimize thermo-mechanical stress on the conductive ribbons.

7. The module of claim 1, wherein the vapor barrier layer has a thickness between 0.5 millimeters and 6 millimeters.

8. A photovoltaic module, comprising:
a plurality of electrically interconnected photovoltaic cells, each cell including a semiconductor absorber layer and a substrate upon which the absorber layer is supported;
a transparent barrier frontsheet overlying the cells and configured to protect the cells from environmental elements while allowing substantial passage of solar radiation to the cells; and
a multi-layer backsheet underlying the cells and including a vapor barrier layer;
wherein the substrate and the vapor barrier layer are constructed from one or more materials having substantially similar coefficients of thermal expansion.

9. The module of claim 8, wherein the cells are interconnected by conductive ribbons constructed from a material having a substantially similar coefficient of thermal expansion to the coefficients of thermal expansion of the substrate and the barrier layer.

10. The module of claim 9, wherein the conductive ribbons, the substrate and the barrier layer are all constructed from stainless steel.

11. The module of claim 10, wherein the stainless steel of the barrier layer is heat treated to reduce thermo-mechanical stress between the barrier layer, the conductive ribbons, and the substrate.

12. The module of claim 11, wherein the stainless steel of the barrier layer is tempered.

13. The module of claim 11, wherein the stainless steel of the barrier layer is annealed.

14. The module of claim 8, wherein the vapor barrier layer has a thickness between 0.5 millimeters and 6 millimeters.

15. A photovoltaic module, comprising:
a plurality of electrically interconnected photovoltaic cells, each cell including a semiconductor absorber layer and a substrate upon which the absorber layer is supported;
a transparent barrier frontsheet overlying the cells and configured to protect the cells from environmental elements while allowing substantial passage of solar radiation to the cells; and
a multi-layer backsheet underlying the cells and including a vapor barrier layer;
wherein the substrate and the vapor barrier layer are constructed from one or more materials having properties configured to provide the photovoltaic module with a predetermined amount of curvature.

16. The module of claim 15, wherein the predetermined amount of curvature is chosen to match curvature of a structure to which the module is configured to be attached.

17. The module of claim 15, wherein the predetermined amount of curvature is chosen to counteract adhesive creep of an adhesive used to hold the module to a mounting structure.

18. The module of claim 15, wherein the predetermined amount of curvature is chosen to match curvature of a structure to which the module is configured to be attached after counteracting adhesive creep of an adhesive used to hold the module to the structure.

19. The module of claim 15, wherein the substrate and the vapor barrier layer are constructed from materials having coefficients of thermal expansion that differ by a predetermined amount.

20. The module of claim 15, wherein the frontsheet is pre-shrunk by exposure to an elevated temperature.

21. The module of claim 15, wherein lamination of the frontsheet to the cells contributes to the predetermined amount of curvature.

22. The module of claim 15, wherein the predetermined amount of curvature is zero.

23. The module of claim 15, wherein the vapor barrier layer has a thickness between 0.5 millimeters and 6 millimeters.
